(19) United States
(12) Patent Application Publication
(10) Pub. No.: US 2006/0048893 A1
(43) Pub. Date: Mar. 9, 2006

(54) Atmospheric pressure plasma processing reactor

(75) Inventors: Gary S. Selwyn, Los Alamos, NM (US); Ivars Henins, Los Alamos, NM (US); Hans R. Snyder, Los Alamos, NM (US); Hans W. Herrmann, Los Alamos, NM (US)

Correspondence Address: UNIVERSITY OF CALIFORNIA;LOS ALAMOS NATIONAL LABORATORY, P.O. BOX 1663, MS A187, LOS ALAMOS, NM, 87545, US

(73) Assignee: The Regents of the University of Califonia

(21) Appl. No.: 11/127,865

(22) Filed: May 11, 2005

Related U.S. Application Data
(63) Continuation-in-part of application No. 10/208,124, filed on Jul. 29, 2002, now abandoned.

(51) Int. Cl. C23F 1/00; C23C 16/00

(52) U.S. Cl. 156/345.43; 216/67; 118/723 E

(57) ABSTRACT

A non-arcing atmospheric pressure plasma processing reactor that includes a wafer platform that is electrically conductive and operatively placed near at least one radio frequency electrode to allow the creation of an electric field. An rf power supply is electrically attached to both the radio frequency electrode and the wafer platform to create said electric field for generation of said non-arcing atmospheric pressure plasma. A process gas supply comprising a mixture of 90% to 99% support gas to 1 % to 10% reactive gas is supplied to the electric field to generate the atmospheric pressure plasma.

### RELATED APPLICATIONS

This is a continuation-in-part application out of U.S. patent application Ser. No. 10/208,124, filed Jul. 29, 2002, now abandoned.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention generally relates to plasma generation for use in material treatment, deposition or etching processes, and, more specifically to a processing reactor for generating plasma at atmospheric pressure to be used for treatment of a silicon wafer or material substrate.

### BACKGROUND OF THE INVENTION

Integrated circuits have become pervasive components of a myriad of products that the world uses everyday. Integrated circuits are found in household products, cell phones, computers, radios and virtually thousands of additional applications. Because of the demand for these products, it is imperative that the manufacture of integrated circuits produces efficacious and reliable devices in the most efficient and cost effective manner possible.

One of the critical steps in the manufacture of integrated circuits is the step of plasma ashing, or removal, of photoresist. Photoresist is an organic, photosensitive compound that is applied as a thin film over a wafer or other substrate in order to photographically transfer a circuit pattern to the surface of the wafer. The photoresist is first “developed” with the circuit image and then the developed photoresist is used as a mask to selectively define regions of the wafer that will be etched using chemically reactive plasma. After the silicon etching process is complete, and the etched pattern has been transferred to the wafer, the residual photoresist mask must be removed, or “ashed” off the surface of the wafer in preparation for the next process step. It is important that removal of all the photoresist material from the wafer be done in this ashing step, to avoid contamination in subsequent process steps. As used herein, the term “wafer” shall mean any material substrate, including but not limited to silicon wafers, glass panels, plastics, dielectrics, textiles or nonwovens, metal films or semiconductor materials. Similarly, the “ashing” process shall mean any surface treatment step accomplished on a substrate, including but not limited to deposition of thin films, etching, cleaning, and surface modification methods.

Present systems for achieving photoresist removal include wet processes (e.g. solvents) and dry processes that are accomplished by oxidation of the photoresist layer using ozone or oxygen-containing plasmas. The latter method is often called photoresist “ashing.” Wet photoresist removal steps generate chemical waste, which must be disposed of properly. Dry processes, such as plasma ashing, involve the use of a vacuum chamber in which the plasma is generated, which increases the cost of the equipment. A drawback in the use of ozone for photoresist removal is the danger and toxicity of this relatively unstable, noxious gas.

Plasma ashing is the generally preferred means of photoresist removal. However, because wafers are individually processed in vacuum, each step requires a separate vacuum chamber in order to avoid chemical contamination between sequential process steps. Naturally, with multiple vacuum chambers, a wafer must be moved from one chamber to the next, slowing wafer throughput. In addition, each vacuum chamber must have separate gate valves, vacuum pumps and gauges. This increases the cost and complexity of the process. Multiple process steps are often desirable to use in photoresist ashing, or other surface treatment methods, as described herein. While the use of multiple processing steps is possible using the prior art, the need for separate vacuum process chambers to accommodate the different chemistries adds to the cost and complexity of the present method, and reduces wafer throughput.

In some process steps required for device fabrication, ion implantation is used to change the conductivity of the silicon matrix. When using this process, it is necessary that selected regions of the silicon substrate be exposed to certain ions having a desired kinetic energy in order to be implanted into the silicon substrate to a desired depth, so that the localized electrical properties of the semiconductor wafer are changed in a desired manner.

Photoresist masking is also used in an ion implantation process. In those regions of the semiconductor wafer where photoresist is present, the photoresist acts as a barrier, preventing ion implantation in those regions, but allowing the ions to penetrate in those regions where the photoresist is not present. The high energy and chemical properties of the ions cause the surface of the photoresist to harden and polymerize, forming a thick “skin” that that makes removal more difficult. As a further complication, inorganic species from the ion implantation process become embedded in this thickened “skin”.

Because the ions are typically As⁺, B⁺, or P⁺, the hardened photoresist is no longer a purely organic compound capable of reaction with oxygen plasmas to form volatile etch products, such as CO, CO₂ and H₂O. To remove the hardened photoresist, halogen plasma reactants, such as atomic fluorine, in addition to atomic oxygen, are often required. Accordingly, fluorine-based feed gases, such as CF₄, are used in the plasma to generate the necessary atomic fluorine, which is highly reactive to both photoresist and to the dopant species, thereby helping to etch away the implanted surface of the hardened photoresist. The use of halogen chemistry in the photoresist also converts the embedded ions into their respective halides. This is useful because the halogenated ion-implanted species may generally be removed by dissolving in water, similar to the method taught in U.S. Pat. No. 6,546,938. Of course, if a fluorine-based process is operated for too long a period and the photoresist is completely removed, there is danger of the fluorine atoms reacting with the silicon substrate, causing undesirable and uncontrolled etching of the silicon substrate and damage to the circuit components. For this reason, diligent ashing of hardened photoresist calls for a short exposure to a fluorine-containing plasma, used to remove the upper layers of the hardened photoresist, followed by a second plasma exposure to a pure oxygen plasma, in order to avoid etching of the silicon substrate.

Plasma ashing of hardened photoresist requires at least two process steps: one with an aggressive plasma step, employing either high energy ions to cause sputtering to occur or reactive ion etching with a fluorine-based process chemistry; and the other involving a gentle, oxygen-based chemistry for removal of the soft photoresist remaining after the hardened skin has been removed and to avoid damage to the underlying device. This is the most expensive and complicated approach since it requires two vacuum process chambers, dual pumps and gauges, and a means of moving wafers between the two process chambers, while keeping them in vacuum.

The removal of ion-hardened photoresist in a conventional vacuum-based plasma ashing tool is a slow and expensive undertaking. Similarly, a “wet” cleaning step to remove halogenated inorganic compounds cannot easily be integrated into a vacuum process. In addition to the necessary two process chambers, there also must be an automated load-lock chamber that functions as an interface between atmospheric pressure and the vacuum environment of the ashing tool.

The present invention simplifies the process, and provides ashing capability far superior to the prior art, especially for treating hardened photoresist. Unlike the prior art, the present invention provides a novel means for providing a continuous variation in plasma density and ion flux needed to remove the hardened “skin” of ion-implanted photoresist, while also providing a gentle plasma that will not damage the underlying device elements, once the photoresist is removed. The invention does this at less cost than the conventional technology because of the much higher efficiency attained. Because vacuum is not required, the present invention is compatible with a subsequent “wet” cleaning step to remove halogenated chemical compounds that do not have a sufficient vapor pressure for removal in the gas phase but can be dissolved in water. The present invention accomplishes these improvements through use of an atmospheric pressure system that permits completion of several process steps without the need for vacuum transfers and without the possibility of cross contamination between the process units.

The present invention uses topographically designed, interchangeable electrodes that may be used separately or in combination to provide either an ion-enhanced density plasma or a lower ion density plasma selected to the needs of the user. The ion-enhanced density plasma process can be used to remove a hardened top surface of the photoresist; whereas, the lower ion density plasma would be used to remove conventional photoresist (i.e., not ion-implanted) or ion-implanted photoresist after the hardened skin had been removed.

In U.S. Pat. No. 6,051,150, issued Apr. 18, 2000, to Takuya Miyakawa, a plasma etching method is described. The Miyakawa invention belongs to the class of atmospheric pressure plasma discharges generally known as dielectric barrier discharges (DBDs). DBDs are sometimes also referred to as “corona” discharges. DBDs require an insulating or dielectric cover on one or both of the electrodes to prevent arcing but are capable of operation at atmospheric pressure with a wide variety of process gases. The use of helium as a majority gas (i.e., >=50%) in the space between the electrodes makes the discharge more spatially uniform and less prone to momentary arcing than DBDs operated without a helium-based majority gas. Arcing is undesirable because it leads to contamination of the discharge by vaporizing parts of the electrode material and because arcing damages the substrate.

The dielectric present in the Miyakawa invention is defined as “A glass or other substrate (9), which may be used for a liquid crystal panel”. This clearly identifies that the substrate in the Miyakawa invention must be a dielectric, as it would not be possible to use a conductor or a semiconductor as a substrate to support below the wiring of a liquid crystal panel. Whereas, in the present invention, it is the process conditions that allow plasma treatment without the necessity of a dielectric material to prevent arcing.

This point is made even clearer in another patent involving the same inventor, U.S. Pat. No. 6,006,763, issued Dec. 28, 1999, to Mori et al. The '763 patent teaches the same gas distribution method and shows the same plasma discharge as in the '150 patent. However, the specification of the '763 patent explains, “although the invention has been described in its preferred forms . . . it is understood that . . . details of construction and the combination and arrangement of parts may be changed too . . . For example, each of the surface treatment apparatuses may preferably have either or both electrodes coated with an insulator or a dielectric material similar to the example shown in FIG. 14 in order to cause discharge to take place uniformly”.

Thus, even in the most general case described in the '763 patent, a dielectric cover on the electrode is needed for operation of the plasma. FIG. 14 in the '763 patent shows the electrodes covered with a dielectric material and operating with the same process gases as in the other examples. Because the '763 patent was filed 19 months after the '150 patent and involved the same inventor in both patents, this demonstrates that the discharge parameters being used by Miyakawa in the '150 patent relied upon a dielectric substrate for operation and that use of this form of plasma technology was routine in their laboratory at the time. Thus, the present invention is novel with respect to operation without the need for a dielectric material to prevent arcing. The present invention is necessary to achieve photoresist ashing on a silicon wafer, because a silicon wafer is not a dielectric and so could not simply be substituted for the glass panel in the '150 or '763 patents.

For purposes of discussion herein, a vacuum chamber is defined as a vacuum-tight, sealed unit capable of being pumped down to a sustainable low base pressure and refilled with the process gas for the purpose of generating a plasma. It also would be fitted with necessary vacuum pumps and vacuum gauges, and would be entirely constructed of vacuum-compatible materials.

An enclosure used with the present invention is defined as a leak-tight box that can contain a mix of process gas without contamination from outside air and which provides the necessary means for prevention of operator exposure to hazardous gases generated by the plasma. An enclosure herein does not need the structural stability required for vacuum operation and does not use vacuum pumps, vacuum gauges or load-locks capable of transferring substrates from room air to a vacuum chamber.

As used herein, an atmospheric pressure plasma is defined as a plasma operating at pressure in excess of 200 Torr and less than 10000 Torr.

Additional objects, advantages and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

In accordance with the purposes of the present invention, as embodied and broadly described herein, the present invention comprises a non-arcing atmospheric pressure plasma processing reactor that includes a wafer platform that is electrically conductive and operatively placed near at least one radio frequency electrode to allow the creation of an electric field. An rf power supply is electrically attached to both the radio frequency electrode and the wafer platform to create said electric field for generation of said non-arcing atmospheric pressure plasma. A process gas supply comprising a mixture of 90% to 99% support gas to 1% to 10% reactive gas is supplied to the electric field to generate the atmospheric pressure plasma.

### BRIEF DESCRIPTION OF THE DRAWINGS

The accompanying drawings, which are incorporated in and form a part of the specification, illustrate the embodiments of the present invention and, together with the description, serve to explain the principles of the invention. In the drawings:

FIG. 1 is a pictorial view of one embodiment of the present invention.

FIG. 2 is a pictorial side view of one embodiment of the present invention.

FIG. 3 is pictorial view of a grooved electrode configuration.

FIG. 4 is pictorial view of a showerhead electrode configuration.

### DETAILED DESCRIPTION

The present invention provides plasma processing of substrates and provides the ability for the substrates to undergo sequential processing by multiple plasma processors within a single enclosure. The present invention allows a wafer to be exposed to sequentially different process conditions, such as a dense plasma, “dense” is hereinafter defined as on the order of 10¹¹ e⁻/cm³ (typical of vacuum-based, high density plasmas, such as inductively-coupled plasmas), to a less dense plasma, “less dense” is hereinafter defined as on the order of 10⁹e⁻/cm³ (typical of vacuum-based, capacitively-coupled plasmas), all within the same processor or in adjacent processors, which can treat wafers without the need for moving wafers between separate vacuum chambers.

The present invention may also be used to etch photoresist, silicon and metal from semiconductor wafers, as well as to deposit thin films, coatings used for architectural window glass, and deposition of magnetic films or hermetic coatings on magnetic media. It may also be used for cleaning of surfaces, such as glass panels or sheets of metal, to remove corrosion or surface oxidation. It may be used in combination with an aqueous-based cleaning process for sequential processing from a plasma to a “wet” cleaning step without the need to transfer through load-locks or pressure equalization steps.

The present invention may also be used to continuously treat rolls of fabric, including woven, knitted, or non-woven materials, and rolls of plastic or polymer by placing a roll on both ends of the process region and moving the continuous substrate from one roll to the other, exposing the continuous substrate to the plasma while doing so. In this method, multiple process units offer the advantage of being able to achieve, for example, plasma polymerization in the first plasma unit that the substrate is exposed to, followed by a second plasma treatment, such as thin-film deposition, to encapsulate the polymerized chemical by covering it with the film.

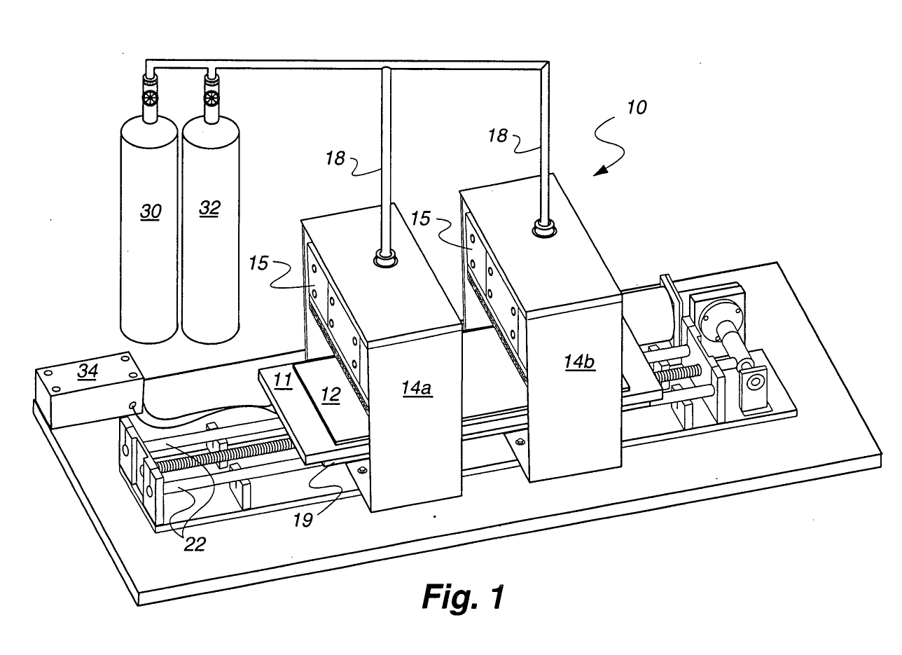

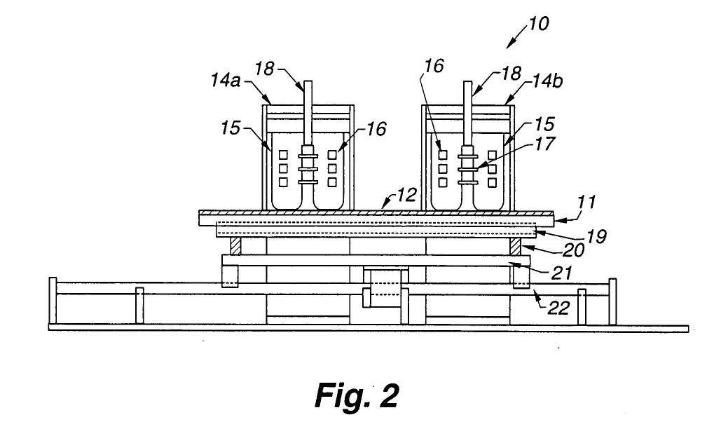

Referring now to FIGS. 1 and 2, where pictorial views of one embodiment of plasma processing reactor 10 are shown. Electrically conductive wafer platform 11 transports wafer 12 to be processed by two atmospheric pressure plasma jet processors 14a, 14b. Both atmospheric pressure plasma processors 14a, 14b, contain electrode 15. Each electrode 15 is operatively located in proximity to wafer platform 11, and may include optional temperature control channels 16 and gas baffles 17.

As previously discussed, each processor may be set up differently in order to provide differing treatments as wafer 12 moves along plasma processors 14a, 14b (the processing area). For example, first processor 14a may operate with a fluorine-containing process gas that is very chemically reactive for initial etching of the hard-to-remove coating, whereas the second processor 14b may operate with an oxygen or carbon dioxide-containing process gas that is less chemically reactive to silicon, but reactive enough to remove photoresist that is not hardened.

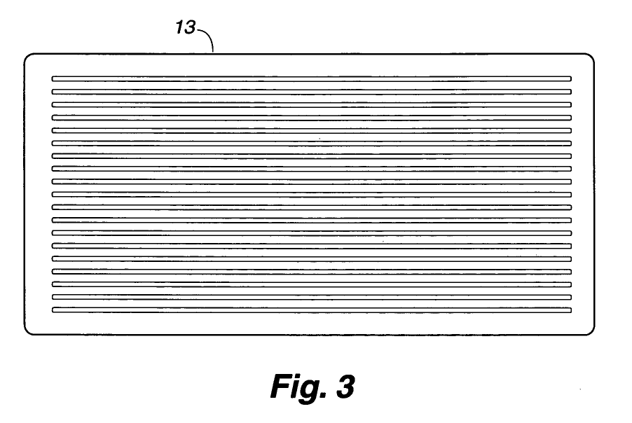

Alternatively, the physical dimensions of each processor may differ in is order to provide differing wafer treatment. For example, first processor 14a may use grooved electrode 13 (see FIG. 3), which can be orientated either perpendicularly to the direction of travel, or at some angle ranging from 0 to 90 degrees relative to the direction of movement, enhancing the density of the plasma. Second processor 14b electrode 15 may have no grooves at all thereby providing a less dense plasma than first processor 14a. For example, a processor with no grooves can be employed for gentle ashing, which is desirable near the end of the photoresist removal process (to avoid wafer damage).

As yet another alternative, first processor 14a may be operated at 40.68 MHz to provide a more dense plasma, whereas second processor 14b may be operated at 13.56 MHz, to achieve slower etching of the photoresist after the hardened “skin” has been removed.

Thus, multiple combinations are envisioned that include changing process chemistry and physical processor attributes to perform wafer treatment. Also note that one is not limited to move wafer 12 in a linear fashion; wafer 12 may instead be mounted on a table that can be rotated, thereby moving wafer 12 in a manner that it may pass through just sections of plasma created by processors 14a, 14b. This is advantageous when a “wet”, aqueous-based cleaning step is to be included with the plasma processing apparatus to help remove halogenated inorganic compounds. Alternatively, a conveyor-belt operation may be used to continuously move wafers along the same axis of motion, similar in movement to the reel-to-reel movement for textiles, plastics and nonwovens described above.

A process gas, comprising plasma support gas 30 and reactive gas 32 is introduced through gas inlet 18. A process gas mixture of 90-99% support gas 30 provides a stable, atmospheric plasma between electrode 15 and wafer platform 11 without the need for dielectric covers to prevent arcing around the edges of the material being treated. In a preferred embodiment, a process gas mixture of 95-99% support gas 30 is used.

Gases that may be used as plasma support gases 30 include: helium, neon, and argon. Gases that maybe used as reactive gases 32 include: halogen-containing gases, such as CF₄, NF₃, C₂F₆, Cl₂, CF₃H, or SF₆. Either NF₃ or CF₄ is preferred because they are non-hazardous, inexpensive and readily available.

RF power supply 34 is capacitively coupled to electrodes 15 and may be used with a fixed or variable tuning network if the impedance of electrodes 15 is not 50 ohms. RF power supply 34 is used for generating the atmospheric plasma by creating an electric field between electrode 15 and platform 11. Either electrode 15 or platform 11 may be RF-powered. In most cases, it is preferred to rf-power electrode 15 and ground wafer platform 11 for safety reasons. The specific frequency and voltage of the RF energy is determined based on the particular process step to be employed for a particular wafer 12. The frequency of RF power supply 34 is between 1 MHz and 100 MHz, and 27.12 or 40.68 MHz are used in preferred embodiments.

Note that when the above plasma excitation frequencies are used in combination with the gas mixtures described above with an operative electrode gap that is between 0.1 and 1 cm between the rf electrode and the ground electrode, it is possible to obtain the desired non-arcing plasma discharge conditions without the need for dielectric covers on the electrodes.

Each processor may be controlled independently, both with respect to RF energy and process chemistry (different process gas mixtures). For example, first processor 14a could utilize a He/CF₄ process gas mixture, while second processor 14b could utilize a He/O₂ or He/CO₂ process gas mixture. Thus, two process steps may be performed instead of the typical one step provided by a conventional reactor. Similarly, different processes may be run in the two reactors. The first reactor may clean the substrate, removing surface oxide or corrosion, while the second is used to deposit a thin film or to etch into the substrate. Close proximity between the two processors would enable the cleaning step used to remove a surface oxide so that the second process unit could be used to efficiently etch the substrate with a different chemistry than that used in the first process unit. Close proximity is needed because the time spent moving the substrate from one processor to the other must be short relative to the time required for reformation of an oxide film. Note, that in another embodiments, additional processors could be used to perform finishing steps on wafer 12.

Temperature control fluids, such as air, water or oil, may be circulated through temperature control channels within processors 14a, 14b to regulate the temperature of electrode 15. Note that in some cases, it also might be desirable to heat electrodes 15 or platform 11, either resistively, or by passing a heated fluid through temperature control channels. In either case, temperature control may be employed to control the temperature of the formed atmospheric plasma or the temperature of the silicon wafer during processing.

Referring to FIG. 2, wafer platform 11 sits above electric heating rods 19 that are supported by ceramic insulators 20, which, in turn, rest on slide carriage 21. Heating rods 19 serve to heat wafer 12 to an appropriate temperature for processing when such action is required. Slide carriage 21 moves along translating slide rails 22 when propelled by a motive force (e.g. electric motor, conventional slide drive screw, or conveyor belt). In another embodiment, wafer 12 can remain stationary and electrode 14 can be moved over wafer 12. It only is necessary that relative movement between wafer 12 and electrode 15 be created. It is also possible to move processors 14a, 14b relative to wafer 12, while keeping wafer 12 stationary on wafer platform 11. One case in which movement of processors 14a, 14b would be preferable is when wafer 12 is large or heavy and therefore subject to damage or distortion by movement or when heavier motors are required to move wafer 12 than to move processors 14a, 14b.

As wafer 12 is moved along first processor 14a it is first subjected to a dense plasma, useful for removal of the hardened photoresist layer, and as wafer 12 continues to move across second processor 14b it is subjected to a less dense plasma, useful for removal of the softer photoresist under the hardened layer. In this way, damage to wafer 12 is avoided once the photoresist layer is fully removed.

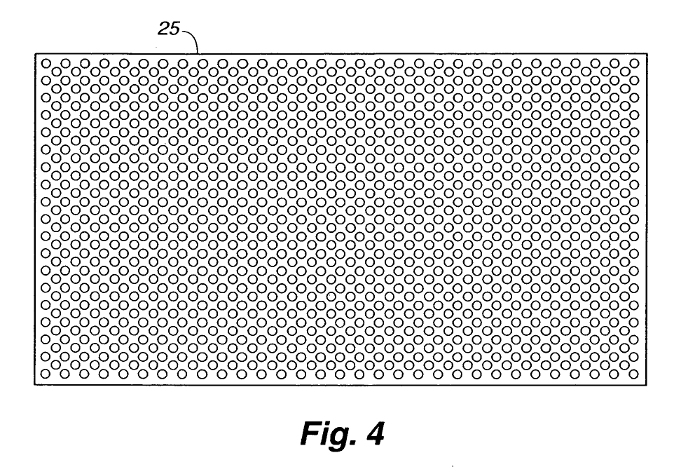

Referring now to FIG. 4, which pictorially shows showerhead electrode 25 configuration that may be used'as electrode 15 in the present invention. A showerhead configuration comprises of a series of small holes in a regular pattern and is used for uniform distribution of gas into the plasma volume between showerhead electrode 25 and platform 11. A large area electrode, such as showerhead electrode 25, is capable of treating more area, resulting in increased wafer 12 throughput. Another embodiment of showerhead electrode 25 may be a grooved (not shown) with holes throughout the electrode for gas flow in addition to the grooves used for enhancement of the plasma density.

The large area electrode, showerhead electrode 25, must first operate off the edge of wafer 12 and directly over the conducting electrode (platform 11) as the process is initiated. The present invention allows this process to occur without any possibility of arcing between showerhead electrode 25 and platform 11. Whereas, if this same evolution were to take place with the invention described in the '150 patent, arcing will occur on the wafer and would damage the wafer and the circuits therein. Even if a dielectric substrate, such as a glass panel, were placed on the electrode of the '150 patent as described, but the substrate was moved fully out and into the plasma region, arcing would occur at points off and near the edge of the substrate, unless the electrode was fully covered by a second dielectric cover. The arcing that is produced would damage the substrate as well as the electrodes.

The showerhead electrode design of the present invention is also compatible with round substrates and it has been demonstrated that plasma ashing of photoresist on 150 mm (6″ diameter) wafer 12, using a 13″×5″ showerhead electrode 25, was conducted without any arcing, even on parts of platform 11 that are not covered by wafer 12. Note that showerhead electrode 25 may be made as large as is needed; the only constraint is the size of the stage used to move platform 11. Normally, showerhead electrode 25 would not be wider than platform 11, but could be wider than wafer 12.

The showerhead design works well for large area processing using plasmas because fresh gas is added equally to all regions of the plasma, leading to better uniformity of treatment. This results in better uniformity of treatment than with a line source because the reactive gas is consumed by surface reactions as it spreads across the substrate.

Therefore, the present invention offers the following advantages: first, it eliminates the need for any vacuum equipment, simplifying maintenance of the equipment and greatly reducing the cost of the equipment; second, it etches or cleans, or deposits thin films on wafers or substrates faster because of high reactive species gas density and in-situ exposure to the plasma, so its throughput is greater; third, it has the ability to run multiple process steps almost simultaneously, even those requiring different process chemistries, resulting in reduced equipment and process complexity; and, finally, wafer handling is faster as multiple wafers are moved simultaneously, rather than sequentially, also enhancing wafer throughput.

The foregoing description of the embodiments of the invention has been presented for purposes of illustration and description. It is not intended to be exhaustive or to limit the invention to the precise form disclosed, and obviously many modifications and variations are possible in light of the above teaching. The embodiments were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A non-arcing atmospheric pressure plasma processing reactor comprising:
a. a wafer platform that is electrically conductive,
b. at least one radio frequency electrode operatively placed near said wafer platform to allow creation of an electric field between said wafer platform and said at least one radio frequency electrode,
c. an rf power supply electrically attached to said at least one radio frequency electrode and said wafer platform to create said electric field for generation of said non-arcing atmospheric pressure plasma,
d. a process gas supply comprising a mixture of 90% to 99% support gas to 1% to 10% reactive gas to create said non-arcing atmospheric pressure plasma in the presence of said electric field; and
e. a means for introduction of said process gas into said electric field.

2. The non-arcing atmospheric pressure plasma processing reactor of claim 1, where said radio frequency electrode is a shower head electrode that provides for uniform distribution of said process gas into said non-arcing atmospheric pressure plasma.

3. The non-arcing atmospheric pressure plasma processing reactor of claim 1, where said radio frequency electrode is a grooved electrode that enhances the density of said non-arcing atmospheric pressure plasma.

4. The non-arcing atmospheric pressure plasma processing reactor of claim 1, where said process gas supply comprises a mixture of 95% to 99% support gas to 1 % to 5% reactive gas.

5. The non-arcing atmospheric pressure plasma processing reactor of claim 1, where said support gas is selected from the group consisting essentially of: helium, neon, and argon.

6. The non-arcing atmospheric pressure plasma processing reactor of claim 1, where said reactive gas is selected from the group consisting essentially of: CF₄, O₂, CO₂, NF₃, C₂F₆, Cl₂, CF₃H, and SF₆.

7. The non-arcing atmospheric pressure plasma processing reactor of claim 1, where said reactive gas is CF₄.

8. The non-arcing atmospheric pressure plasma processing reactor of claim 1, where said reactive gas is NF₃.

9. The non-arcing atmospheric pressure plasma processing reactor of claim 1, where said rf power supply outputs a frequency in a range of about 1 MHz to 100 MHz.

10. The non-arcing atmospheric pressure plasma processing reactor of claim 1, where said rf power supply outputs a frequency of 27.12 MHz.

11. The non-arcing atmospheric pressure plasma processing reactor of claim 1, where said rf power supply outputs a frequency of 40.68 MHz.

12. A method for surface treatment of a wafer with a non-arcing atmospheric pressure plasma, comprising:
a. placing said wafer onto an electrically conductive wafer platform,
b. creating an electric field between said wafer platform and at least one radio-frequency electrode using an rf power supply,
c. directing a process gas supply into said electric field comprising a mixture of 90% to 99% support gas and 1% to 10% reactive gas, thereby creating said non-arcing atmospheric pressure plasma; and
d. moving said wafer through said non-arcing atmospheric pressure plasma to effect change in the surface state of said wafer through exposure to chemical species formed in said non-arcing atmospheric pressure plasma.

13. The method of claim 12, where said non-arcing atmospheric pressure plasma is supplied by a process gas supply comprising a mixture of 95% to 99% support gas to 1% to 5% reactive gas.

14. The method of claim 12, where said rf power supply outputs a frequency in a range of about 1 MHz to 100 MHz.

15. The method of claim 12, where said rf power supply outputs a frequency of 27.12 MHz.

16. The method of claim 12, where said rf power supply outputs a frequency of 40 MHz.

17. The method of claim 12, where said support gas is selected from the group consisting essentially of: CF₄, O₂, CO₂, NF₃, C₂F₆, Cl₂, CF₃H, and SF₆.

18. The method of claim 12, where said support gas is NF₃.

19. The method of claim 12, where said support gas is CF₄.

20. The method of claim 12,where said support gas is selected from the group consisting essentially of: helium, neon, and argon.

21. A method for surface treatment of a wafer with a non-arcing atmospheric pressure plasma, comprising the steps in the following order:
a. placing said wafer onto an electrically conductive platform,
b. creating an electric field between said platform and at least one radio-frequency electrode using an rf power supply,
c. directing a process gas supply into said electric field to generate said non-arcing atmospheric pressure plasma,
d. moving said wafer through said non-arcing atmospheric pressure plasma to convert inorganic chemical compounds on said wafer surface to a form that dissolves in an aqueous solution; and
e. moving said wafer through a wet cleaning step to dissolve said inorganic chemical species.
